(19) United States
(12) Patent Application Publication
(10) Pub. No.: US 2025/0124994 A1
(43) Pub. Date: Apr. 17, 2025

(54) METHOD AND AN APPARATUS FOR DDR5 DIMM POWER FAIL MONITOR TO PREVENT I/O REVERSE-BIAS CURRENT

(71) Applicant: Intel Corporation, Santa Clara, CA (US)

(72) Inventors: Dat T. LE, Tigard, OR (US); George VERGIS, Portland, OR (US); Alejandro LARIOS, Zapopan (MX)

(21) Appl. No.: 18/986,494

(22) Filed: Dec. 18, 2024

(51) Int. Cl. G11C 29/02; G11C 29/14; G11C 29/44

(52) U.S. Cl. CPC G11C 29/021; G11C 29/14; G11C 29/44

(57) ABSTRACT

Methods and apparatus for DDR5 DIMM power fail monitor to prevent I/O reverse-bias current. An apparatus is configured to be implemented in a host system including a processor having an integrated memory controller (iMC) coupled to one or more DIMMs having an onboard Power Management Integrated Circuit (PMIC). The apparatus includes circuitry to monitor an operating state for a host voltage regulator (VR) providing input power to the processor and monitor an operating state of the PMIC for each of the one or more DIMMs. In response to detecting a fault condition of the host VR or a PMIC for a DIMM, the apparatus prevents reverse bias voltage in circuitry in at least one of the iMC and the one or more DIMMs. The apparatus may implement a finite state machine (FSN) having a plurality of defined states including a fault state used to indicate detection of the fault condition.

### BACKGROUND INFORMATION

Traditionally, the DIMM (Dual Inline Memory Module) power delivery solution shares a common “centralized” voltage regulator (VR) on the host motherboard, such as the case for DDR4 (Double Data-Rate 4^{th} generation) applications in client and server platforms. For DDR5 (5^{th} generation), a new DIMM power distribution architecture was introduced to support DDR5 power scaling and accommodating the tighter DRAM's voltage tolerance specification requirements. While the new power distribution architecture provides enhancements, the change from a centralized VR to multiple power domains introduces the potential for reverse bias damage to components in the platform.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram illustrating a system architecture including a host system coupled to a plurality of DIMMs, wherein each DIMM includes a DDR5 PMIC;

FIG. 2a is a diagram illustrating a DDR5 multi-power domain architecture including a CPU integrated memory controller (iMC) coupled to a DDR5 DIMM, further depicting a first example of a reverse bias voltage that may result when the voltage regulator providing input voltage to circuitry on the iMC fails;

FIG. 2b is a diagram illustrating the DDR5 multi-power domain architecture of FIG. 2a, further depicting a second example of a reverse bias voltage that may result when the PMIC providing input voltage to circuitry on the DIMM fails;

FIG. 3 is a diagram illustrating an architecture configured to prevent reverse bias voltage occurrences as a result of VR and PMIC failures, according to one embodiment;

FIG. 4 shows an FPGA that is programmed to operate as a DDR5 power fail interface, according to one embodiment;

FIG. 5 is a table showing the outputs for DRAM_RST, DRAM_PWROK, and PWRGD_FAIL[n:0]_out and error bit values for transition states IDLE, ST_PSU, ST_DDRIO, ST_LINK and ST_FAULT implemented by the FSM (Finite State Machine) enable control logic of the CPLD of FIG. 3, according to one embodiment;

FIG. 6 is an FSM state transition flowchart implemented by the FSM enable control logic of the CPLD of FIG. 3, according to one embodiment;

FIG. 7 is a table showing further details of the transition states for the FSM state transition flowchart of FIG. 6; and

FIG. 8 is a diagram of a computing platform or system implementing the circuitry shown in the architecture of FIG. 3. according to one embodiment.

### DETAILED DESCRIPTION

Embodiments of methods and apparatus for DDR5 DIMM power fail monitor to prevent I/O reverse-bias current are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

Under the DDR5 DIMM specification, the DRAM power supply has been relocated from main board VR (MBVR) to the DIMM. In this new architecture, the CPU (Central Processing Unit) DDR5 subsystem power delivery can be scaled down to meet just the memory controller's I/O (Input/Output) power consumption requirements, while each DIMM comes equipped with its own optimized power supply solution (DIMM Power Management Integrated Circuit (PMIC)). The resulting isolated power domains had to be “stitched back together” (each DIMM and its CPU memory controller power domains) to operate as one. The specific concern arising from multiple independent power domains is the possibility of “reverse bias” component damage. Reverse-bias condition occurs when a device in a particular domain loses power (powered down) but a device in another domain continues to drive power through the I/O signals. Since I/O buffer damage can occur within nanoseconds (nS), neither the MBVR nor the PMIC on the DIMM is suited to prevent rapid reverse biasing of the I/O. The traditional power control typically takes milliseconds to respond.

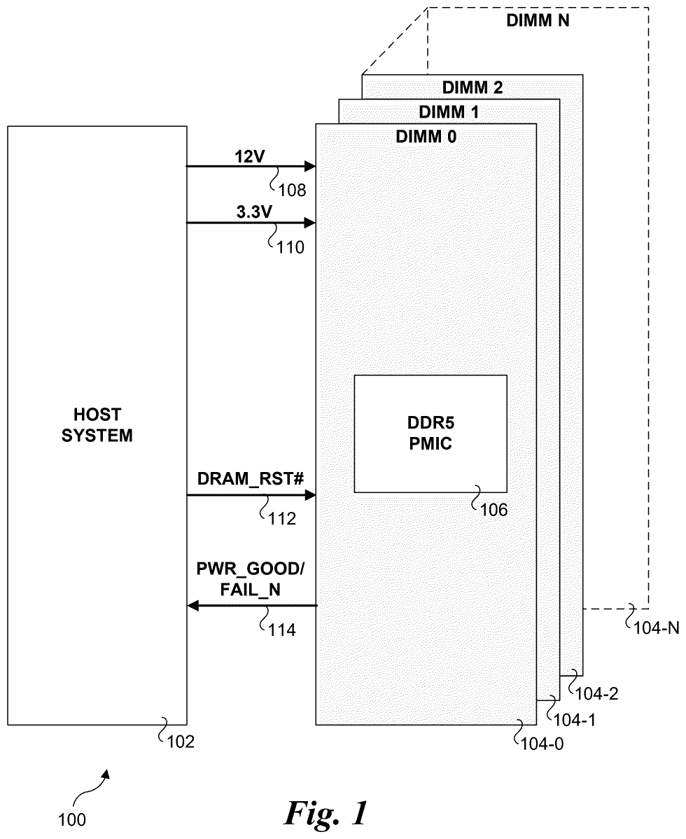

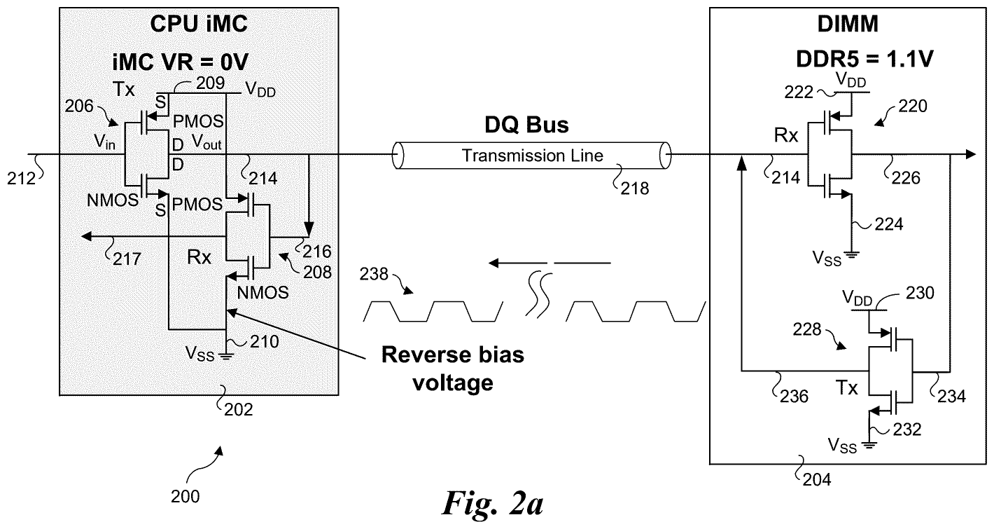

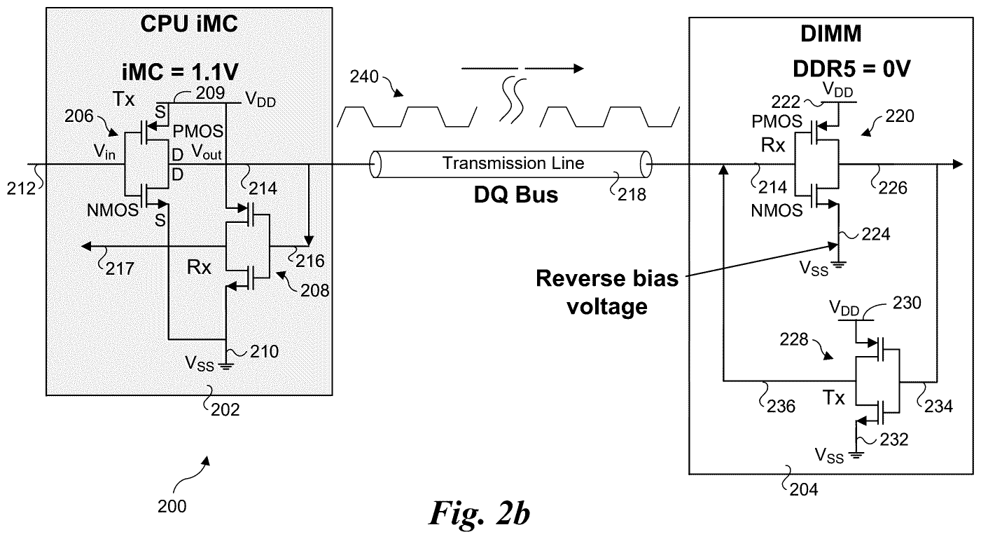

The DDR5 power distribution network and potential reverse biased conditions are shown in FIGS. 1, 2a, and 2b. FIG. 1 shows a system architecture 100 including a host system 102 coupled to a plurality of DIMMs 104-0, 104-1, 104-2, . . . 104-N. Each DIMM includes a DDR5 PMIC 106. Host system 102 may be a motherboard or main board or the like that includes a host CPU or processor and multiple slots in which the DIMMs are installed. The DDR5 DIMMs have specified form factors that include defined pinouts, such as a 288-pin DIMM, for example. The pinout includes pins for receiving power inputs including 12V input 108 and 3.3V input 110. The pinouts also include an input pin for receiving a DRAM_RST # (DRAM reset #) signal 112 and have an output pin providing a signal 114 indicating a power good or power fail condition.

FIGS. 2a and 2b show examples of potential reverse bias voltage conditions under a DDR5 multi-power domain architecture 200 including a CPU integrated memory controller (iMC) 202 coupled to a DDR5 DIMM 204. DIMM 204 will include 12V and 3.3V power inputs 108 and 110 (not shown) and include a PMIC (not shown). Circuitry on DIMM 204 and circuitry on CPU iMC 202 operate in a separate power domains.

iMC 202 is used to control access to memory stored in memory chips on DIMM 204 via I/O signals exchanged between the iMC and DIMM comprising a memory channel or memory bus, as are known in the art and specified by applicable DDR5 standards. This includes I/O signals transmitted from iMC 202 to DIMM 204 and I/O signals transmitted from DIMM 204 and received by iMC 202. The signals transmitted from the iMC will include data signals transmitted to the DIMM via a bi-directional DQ Bus (aka Data Bus) and data signals transmitted from the iMC and received by the iMC via the DQ bus.

Selected circuitry shown on CPU iMC 202 includes a transmit (Tx) buffer 206 and a receive (Rx) buffer 208. Each of those buffers are depicted as CMOS invertors including a PMOS transistor having is source coupled to power (e.g., V_{DD}) and its drain coupled to the drain of an NMOS transistor whose source is coupled to ground (e.g., V_{SS}). For example, Tx buffer 206 has a high-side voltage 209 of V_{DD} and a low-side voltage 210 of V_{SS}. Each CMOS inverter receives an input voltage Vᵢₙ and outputs an output voltage Vₒᵤₜ. The value of Vₒᵤₜ is a function Vᵢₙ, high-side voltage V_{DD}, and low-side voltage V_{SS}. It is noted that there would be similar pairs of Tx and Rx buffers for each lane in the DQ bus, with only a single lane being shown for simplicity. As shown in FIG. 2a, Tx buffer 206 receives an input signal 212 and outputs an output signal 214 that is transmitted onto a lane in DQ Bus 218. Rx buffer 208 receives an input signal 216 and outputs an output signal 217.

Selected circuitry shown for DIMM 204 includes an Rx buffer 220 and a Tx buffer 228. Rx buffer 220 is coupled between V_{DD} 222 and V_{SS} 224 and receives output signal 214 via DQ bus 218 as an input and outputs an output signal 226. Tx buffer 228 is coupled between V_{DD} 230 and V_{SS} 232 and receives output signal 234 as an input and outputs a signal 236.

For simplicity and to avoid crowding, each of Tx buffers 206 and 228 and Rx buffers 208 and 220 are shown as CMOS invertors in FIGS. 2a and 2b. In practice, the Tx and Rx buffers are tri-state buffers that put their output in a high impedance state when in the tri-state mode. The use of tri-state buffers enables the signal lines for the lanes in DQ bus 218 to be shared to provide bi-directional communication over the DQ bus.

FIG. 2a illustrates a first example of reverse bias voltage that may result when the VR input voltage to CPU iMC 202 is 0V, which may occur if the MBVR fails. Meanwhile, the circuitry in DIMM 204 is 1.1V, which is the voltage provided by the PMIC on the DIMM (not shown). When the iMC is receiving data over DQ bus 218 from DIMM 204, the output state of Tx buffer 206 will be in a high-impedance tri-state mode, effectively disconnecting Tx 206 and Rx 220 from the DQ bus. When iMC VR=0V, there is no voltage differential across the PMOS and NMOS transistors. Meanwhile, the voltage of the input data signal (for a given lane) will be modulated between ˜1.1 V (V_{DD} 230) and V_{SS} 232, as shown by signal waveform 238. Since iMC 202 and DIMM 204 have separate power domains, this may create reverse bias voltage that may damage the NMOS transistor in Rx buffer 208.

FIG. 2b shows an example of a situation that may result in reverse bias voltage when there is a PMIC failure on DIMM 204 while DIMM 204 is receiving data from iMC 202 over DQ bus 218. Under this example of a PMIC failure, the voltage provided to circuitry onboard DIMM 204 is 0V rather than 1.1V provided by the PMIC under normal operation. Meanwhile the voltage for CPU iMC 202 is 1.1V, as is the case under normal operation. When iMC 202 is transmitting data over DQ bus 218, the output voltage 214 of Tx buffer 206 is modulated between ˜1.1 V (V_{DD} 209) and V_{SS} 210, as shown by signal waveform 240. Since there is no voltage differential across the PMOS and NMOS transistors in Rx buffer 220 (e.g., both VDD 222 and Vss 224 are 0V) and iMC 202 and DIMM 204 operate in separate power domains, this may result in a reverse vias voltage in Rx buffer 220 that may damage the NMOS transistor.

In accordance with aspects of the embodiments disclosed herein, a solution for addressing the reverse biased voltage issue through a VR interlock mechanism that includes a combinational logic circuit and Finite State Machine (FSM) enable logic. In one embodiment, the VR interlock mechanism is implemented on a Complex Programmable Logic Device (CPLD). The CPLD monitors host MBVR and DRAM_PWRGD signals in real time and manages the system power shutdown accordingly.

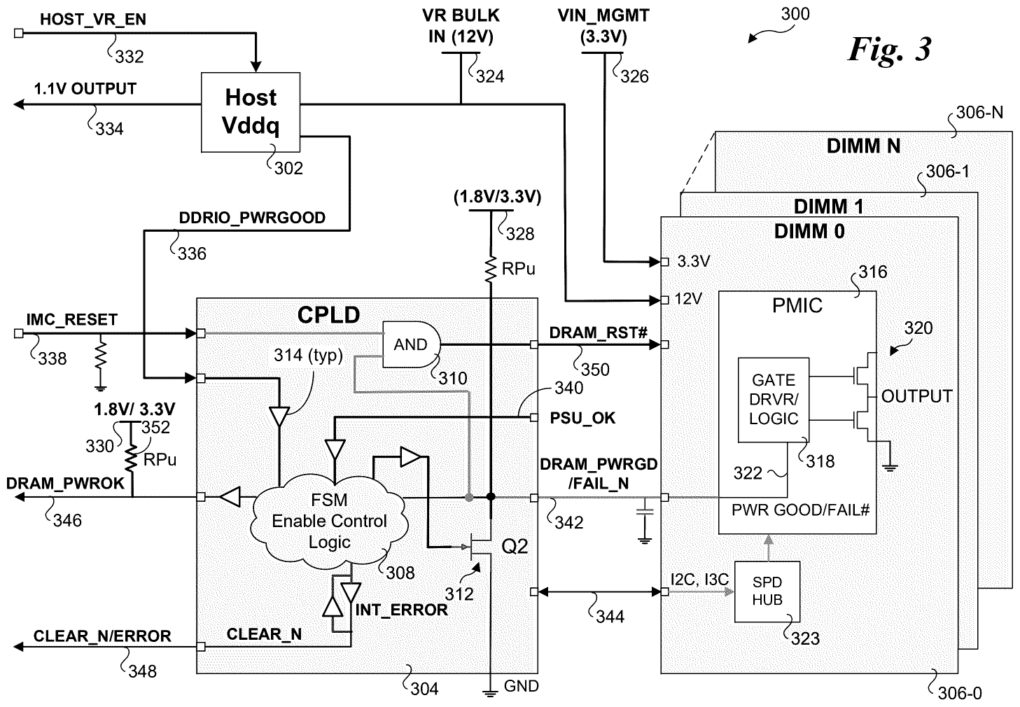

FIG. 3 shows an architecture 300 illustrating an embodiment of the solution. Architecture 300 includes a host Vddq regulator 302, a CPLD (Complex Programmable Logic Device) 304, and a plurality of DIMMs 306-0, 306-1, . . . 306-N. CPLD 304 includes FSM enable control logic 308, a dual-input AND gate 310, an NMOS output driver (Q2) 312 and a plurality of amplifiers 314. Each DIMM 306 includes a PMIC 316 having gate driver/logic 318 providing inputs to an output circuit 320 and an output power good/fail signal 322.

Each DIMM 306 also includes an DDR5 Serial Presence Detect (SPD) hub 323. SPD hub 323 provides functionality defined for an SPD5 Hub and may include an integrated temperature sensor (optional). The SPD hub is configured to communicate with CPLD 304 over an I2C or I3C serial bus 344, in the illustrated embodiment.

The power supply inputs to the circuitry includes a 12V VR BULK IN supply 324, a 3.3V VIN_MGMT supply 326, and 1.8V/3.3V supplies 328 and 330. 12V VR BULK IN supply 324 provides input power to Host Vddq regulator 302, which receives a host VR enable (HOST_VR_EN) signal 332 that is used to enable a 1.1V output 334. Host Vddq also outputs a DDRIO_PWRGOOD signal 336 indicating the power for the DDR IO is good. CPLD 304 receives an IMC_RESET input 338, DDRIO_PWRGOOD signal 336, a PSU_OK signal 340, and a DRAM_PWRGD/FAIL_N signal 342 corresponding to PWR GOOD/FAIL #signal 322 output by gate driver/logic 318. The signals output by CPLD 304 include a DRAM_PWROK signal 346, a CLEAR_N/ERROR signal 348, and a DRAM_RST #signal 350.

The platform's DIMM power delivery management mechanism is accomplished via CPLD 304, which is on the main board. The CPLD's combinational logic circuit consists of a dual-input AND gate 310 and NMOS output driver (Q2) 312 connected to an open-drain signal (DRAM_PWRGD) that terminates externally to 1.8V/3.3V supply 330 via a pull-up resistor (RPu) 352. The host DDRIO_PWRGD I/O signal 336 and DRAM_PWRGD I/O signal 342 are inputs to AND gate 310. The same DRAM_PWRGD I/O signal 336 is also routed as input to FSM enable control logic 308. The output of AND gate 310 drives DRAM_RST signal 350 to the DIMMs.

FSM enable control logic 308 monitors the PWRGD status of the host PSU (Power Supply Unit) and host Vddq regulator 302 and DIMM PMIC 316. CPLD 304 asserts DRAM_RESET # upon detecting any memory sub-system power failure scenario. As a result of the host CPLD asserting DRAM Reset, the memory controller (iMC) and all DDR devices are required to tri-state their IOs within 50 ns. The reset signal tri-stating of the DRAM I/O connect to multiple DIMMs (0 to N) as necessary. Concurrently, the CPLD asserts the DRAM_PWRGD and DRAM_PWRK OK signals and disables the on-DIMM PMIC's rails and host Vddq regulator 302. The CPLD updates its internal Error log status bit for the host to query. Once the immediate reverse bias condition is avoided, the host platform can safely shutdown.

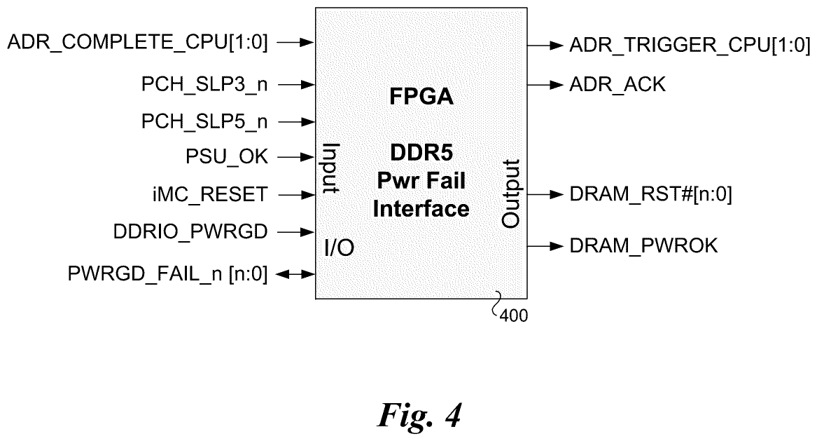

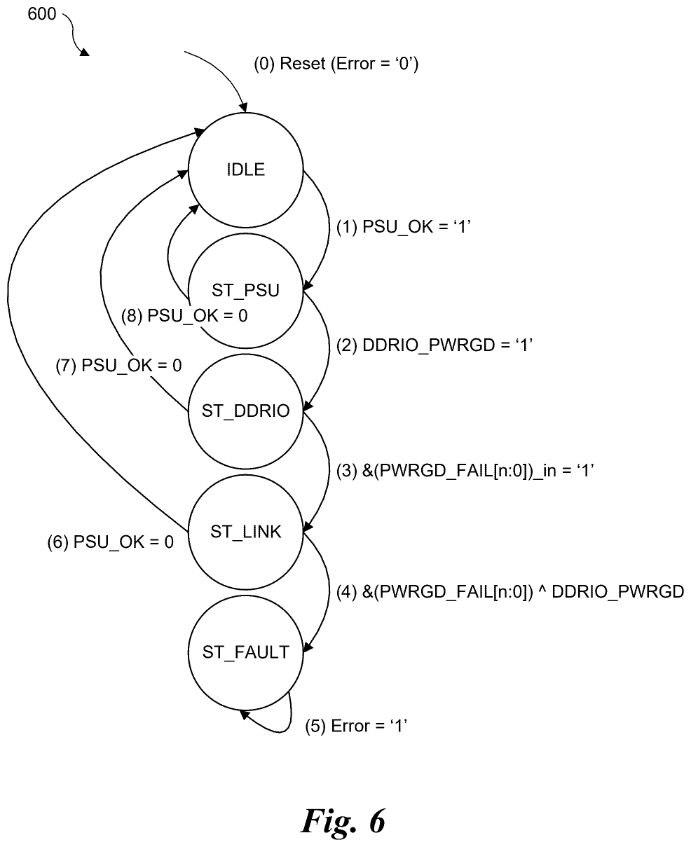

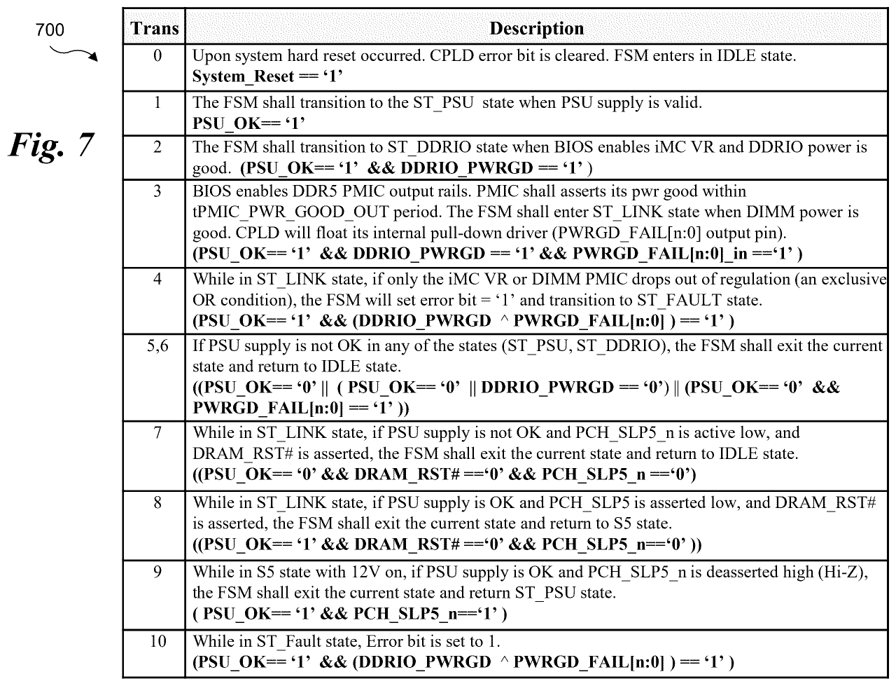

FIG. 4 shows an FPGA (Field Programmable Gate Array) 400 that is programmed to operate as a DDR5 power fail interface, according to one embodiment. The inputs include ADR_COMPLETE_CPU[1:0], PCH_SLP3_n, PCH_SLP5_n, PSU_OK, iMC_RESET, DDRIO_PWRGD, and PWRGD_FAIL_n[n:0]. The outputs include ADR_TRIGGER_CPU[1:0], ADR_ACK, DRAM_RST#[n:0], and DRAM_PWROK. In one embodiment CPLD is an FPGA that is programmed to implement the DDR5 power fail interface in accordance with the FSM logic described and illustrated in FIGS. 6 and 7 below.

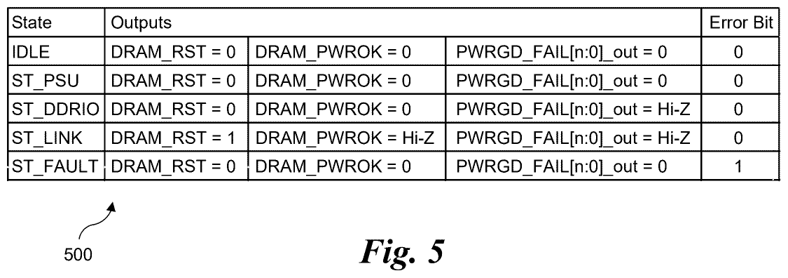

The power domain interlocking flow entails distinctive transition states: IDLE, ST_PSU, ST_DDRIO, ST_LINK and ST_FAULT. FIG. 5 shows a Table 500 illustrating the outputs for DRAM_RST, DRAM_PWROK, and PWRGD_FAIL[n:0]_out and error bit values for each of these transition states. FIG. 6 shows an FSM state transition flowchart 600 with details of the states and transitions shown in Table 700 in FIG. 7. The flowchart begins with a transition (0) upon a platform/system hard reset following an AC power cycle. The CPLD's error bit is cleared, and the FSM enters the IDLE state. When the CPLD detects a ST_PSU power-good signal (logic high), it transitions (1) to the PSU state. In transition (2) the CPLD enters the ST_DDRIO state when the host I/O power domain (e.g., iMC VR13) is valid. Subsequently, the platform BIOS will start powering up the DIMM PMIC by sending the VR Enable command instruction to PMIC's control register bit. The power-on sequence for that specific DIMM has started. The BIOS will also start up the others DIMMs as part of the platform start-up configuration. Upon a successful power-on sequence for each DIMM, its PMIC will float the DRAM_PWRGD signal to indicate a valid power status, as shown for transition (3). The CPLD will only transition to the ST_LINK state when all the DIMMs and host I/O power good are registered a valid status. Upon entry into ST_LINK state, the interlocking across power domains has been achieved. While in ST_LINK state, PSU_OK==‘1’ && DDRIO_PWRGD==‘1’ && PWRGD_FAIL[n:0]) in for lane n==‘1’

As shown by transitions (4) and (5), while in ST_LINK state, if only the iMC VR or DIMM PMIC drops out of regulation (an exclusive OR condition), the FSM will set error bit=‘0’ and transition to ST_FAULT state. In ST_FAULT state, PSU_OK==‘1’ && (DDRIO_PWRGD∧PWRGD_FAIL[n:0]) for lane n==‘1’

As shown for transitions (6), (7), and (8), if the PSU supply is invalid in any of the states (ST_PSU, ST_DDRIO, or ST_LINK), the FSM shall exit the current state and return to IDLE state.

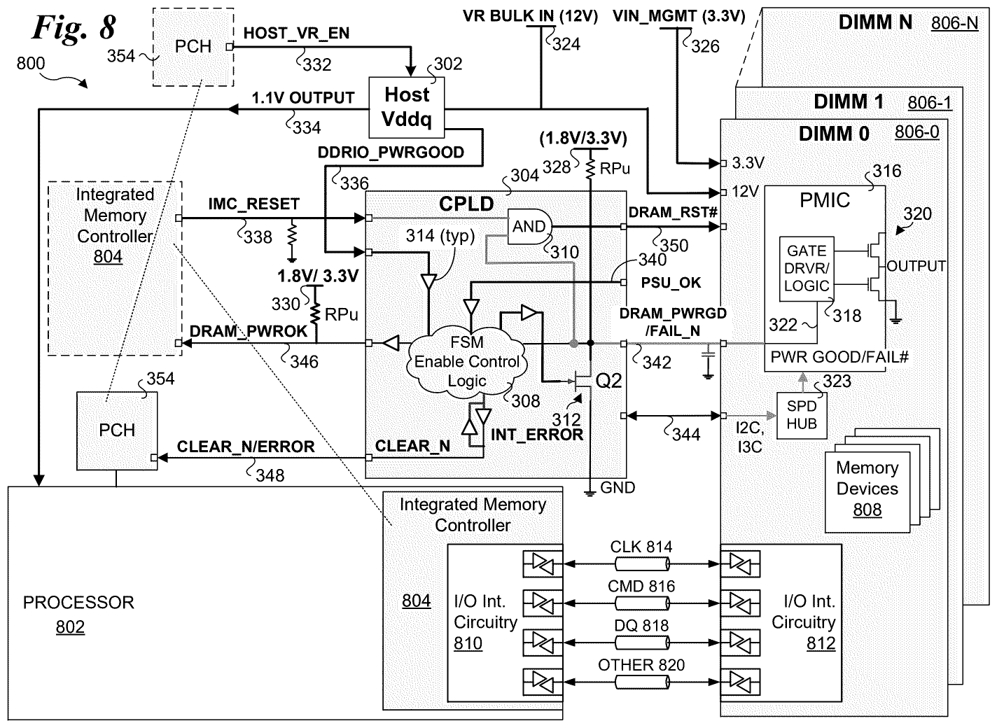

FIG. 8 shows a computing platform or system 800 implementing the circuitry shown in architecture 300 of FIG. 3 presented above, where like-numbered references in FIGS. 3 and 8 refer to the same components and/or circuitry. Platform 800 includes a processor 802 having an iMC 804 coupled to multiple DIMMs 806-0, 806-1, . . . 806-N, also labeled DIMM 0, DIMM 1, . . . . DIMM N. In addition to the components and circuitry for DIMMs 306-0, 306-1, . . . 306-N shown in FIG. 3, DIMMs 806-0, 806-1, . . . 806-N are further depicted as including multiple memory devices 808, such as but not limited to DDR5 memory chips. Platform 800 further shows I/O interface circuitry 810 on iMC 804 and I/O interface circuitry 812 on DIMM 806-0 and a Platform Controller Hub (PCH) 354 coupled to processor 802 that receives CLEAR_N/ERROR signal 348 and outputs HOST_VR_EN signal 332.

I/O interface circuitry 810 and 812 are configured to couple to a memory bus, also referred to as a memory channel. I/O interface circuitry 810 and 812 may include pins, pads, connectors, signal lines, traces, or wires, or other hardware to connect the memory devices, or a combination of these. I/O interface circuitry 810 may include a hardware interface. As shown in FIG. 8, I/O interface circuitry 810 includes at least drivers/transceivers for the depicted signal lines. The transceivers will include tri-state Tx and Rx buffers, as discussed above. Commonly, wires within an integrated circuit interface couple with a pad, pin, or connector to interface signal lines or traces or other wires between devices. I/O interface circuitry 810 can include drivers, receivers (with buffers), transceivers (with buffers), or termination, or other circuitry or combinations of circuitry to exchange signals on the signal lines between iMC 804 and memory device(s) 808. The exchange of signals includes at least one of transmit or receive. While shown as coupling I/O interface circuitry 810 from iMC 804 to I/O interface circuitry 812, it will be understood that in an implementation of system 800 where groups of memory device(s) 808 are accessed in parallel, multiple memory devices can include I/O interface circuitry to the same interface of iMC 804. Instances of similar I/O interface circuitry 810 and 812 may be present for each DIMM 806. DDR5 DIMMs may include support for two memory channels, thus a DDR5 DIMM may include two instances of I/O circuitry 812, which corresponds to a single memory channel, in one embodiment. In some embodiments, processor 802 will include multiple iMCs 804 that may include multiple separate interfaces to one or more memory devices.

In some examples, iMC 804 may be coupled with memory device(s) 808 via multiple signal lines. The multiple signal lines may include at least a clock (CLK) 814, a command/address (CMD) 816, and write data (DQ) and read data (DQ) 818, and zero or more other signal lines 820. According to some examples, a composition of signal lines coupling iMC 804 to memory device(s) 808 may be referred to collectively as a memory bus or a memory channel. The signal lines for CMD 816 may be referred to as a “command bus”, a “C/A bus” or an ADD/CMD bus, or some other designation indicating the transfer of commands. The signal lines for DQ 818 may be referred to as a “data bus” or “DQ bus.”

According to some examples, independent channels may have different clock signals, command buses, data buses, and other signal lines. For these examples, system 800 may be considered to have multiple “buses,” in the sense that an independent interface path may be considered a separate bus. It will be understood that in addition to the signal lines shown in FIG. 8, a bus may also include at least one of strobe signaling lines, alert lines, auxiliary lines, or other signal lines, or a combination of these additional signal lines. It will also be understood that serial bus technologies can be used for transmitting signals between iMC 804 and memory device(s) 808. An example of serial bus technology is 8B10B encoding and transmission of high-speed data with embedded clock over a single differential pair of signals in each direction. In some examples, CMD 816 represents signal lines shared in parallel with multiple memory device(s) 808. In other examples, multiple memory devices share encoding command signal lines of CMD 816, and each has a separate chip select (CS_n) signal line to select individual memory device(s) 808.

In one embodiment, processor 802 comprises a CPU with one or more processor cores. Generally, in addition to processors and CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processing Units (DPUs), Infrastructure Processing Units (IPUs), Edge Processing Units (EPU), Artificial Intelligence (AI) processors or AI inference units and/or other accelerators, FPGAs and/or other programmable logic (used for compute purposes), etc. While some of the diagrams herein show the use of CPUs and/or processors, this is merely exemplary and non-limiting. Generally, any type of XPU may be used in place of a CPU or processor in the illustrated embodiments. Moreover, as used in the following claims, the term “processor” is used to generically cover CPUs and various forms of XPUs.

While various embodiments described herein use the term System-on-a-Chip or System-on-Chip (“SoC”) to describe a device or system having a processor and associated circuitry (e.g., I/O circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., I/O circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Generally, CPLD 304 may comprise a discrete component, such as an FPGA or CPLD chip, or the circuitry shown for CPLD 304 may be integrated in an SoC or SoP. For example, in one embodiment, a processor/CPU/XPU comprises an SoC or SoP including an embedded circuitry comprising an FPGA or CPLD. The embedded circuitry may be implemented on the same die as a processor/CPU/XPU, or on a separate die, tile, chiplet, etc.

The use of DDR5 DIMMs, memory devices, and interfaces is merely exemplary and non-limiting. Generally, the embodiments described and illustrated herein may apply to any existing or future memory device/DIMM technology that includes a PMIC or the like with the memory device/DIMM operating in a power domain that is separate from the host power domain.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

The operations and functions performed by various components described herein may be implemented via embedded hardware or the like, or any combination of hardware and software/firmware. Such components may be implemented as software/firmware modules, hardware modules, special-purpose hardware (e.g., application specific hardware, ASICs, DSPs, etc.), embedded controllers, hardwired circuitry, hardware logic, etc. Software/firmware content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An apparatus configured to be implemented in a host system including a processor having an integrated memory controller (iMC) coupled to one or more Dual Inline Memory Modules (DIMMs) having an onboard Power Management Integrated Circuit (PMIC), the apparatus comprising circuitry to:
monitor an operating state for a host voltage regulator (VR) providing input power to the processor;
monitor an operating state of the PMIC for each of the one or more DIMMs; and
in response to detecting a fault condition of the host VR or a PMIC for a DIMM, prevent reverse bias voltage in circuitry in at least one of the iMC and the one or more DIMMs.

2. The apparatus of claim 1, wherein each of the one or more DIMMs includes a memory channel interface comprising a plurality of input/output (I/O) signals and includes a plurality of transmit and receive I/O buffers for transmitting and receiving data over a DQ bus, and wherein in response to detecting a fault condition the apparatus provides a signal to each of the one or more DIMMs to put its transmit and receive I/O buffers into a tri-state mode.

3. The apparatus of claim 2, wherein the transmit and receive I/O buffers on each of the one or more DIMMs are put into the tri-state mode within 50 nanoseconds of detecting the fault condition.

4. The apparatus of claim 1, wherein the iMC includes a plurality of transmit and receive I/O buffers for transmitting and receiving data over a DQ bus, and wherein upon detecting a fault condition the apparatus provides a signal to the iMC to put its transmit and receive I/O buffers into a tri-state mode.

5. The apparatus of claim 4, wherein the transmit and receive I/O buffers in the iMC are put into the tri-state mode within 50 nanoseconds of detecting the fault condition.

6. The apparatus of claim 1, wherein the apparatus comprises a complex programmable logic device (CPLD).

7. The apparatus of claim 6, wherein the CPLD is programmed to implement a finite state machine (FSN) having a plurality of defined states including a fault state, and wherein a fault condition is detected when the FSM enters the fault state.

8. The apparatus of claim 1, wherein each of the one or more DIMMs is a DDR5 (Double Data Rate 5^{th} generation) DIMM.

9. A computing platform, comprising:
one or more voltage supplies;
a main board (MB) having wiring for interconnecting a plurality of components mounted on or operatively coupled to the main board, including,
a processor with an integrated memory controller (IMC);
a main board voltage regulator (MBVR), coupled to at least one voltage supply and configured to provide regulated voltage input to the processor;
VR interlock circuitry; and
one or more Dual Inline Memory Modules, each including a Power Management Integrated Chip (PMIC) and including one or more input pins coupled to a voltage source;
wherein the VR interlock circuitry is configured to:
monitor an operating state of the MBVR;
monitor an operating state of the PMIC for each of the one or more DIMMs; and
in response to detecting a fault condition of the MBVR or a PMIC for a DIMM, prevent reverse bias voltage in circuitry in at least one of the iMC and the one or more DIMMs.

10. The computing platform of claim 9, wherein each of the one or more DIMMs includes a memory channel interface comprising a plurality of input/output (I/O) signals and includes a plurality of transmit and receive I/O buffers for transmitting and receiving data over a DQ bus, and wherein in response to detecting a fault condition the apparatus provides a signal to each of the one or more DIMMs to put its transmit and receive I/O buffers into a tri-state mode.

11. The computing platform of claim 10, wherein the transmit and receive I/O buffers on each of the one or more DIMMs are put into the tri-state mode within 50 nanoseconds of detecting the fault condition.

12. The computing platform of claim 9, wherein the iMC includes a plurality of transmit and receive I/O buffers for transmitting and receiving data over a DQ bus, and wherein upon detecting a fault condition the apparatus provides a signal to the iMC to put its transmit and receive I/O buffers into a tri-state mode.

13. The computing platform of claim 12, wherein the transmit and receive I/O buffers in the iMC are put into the tri-state mode within 50 nanoseconds of detecting the fault condition.

14. The computing platform of claim 10, wherein the VR interlock circuitry comprises a complex programmable logic device (CPLD).

15. The computing platform of claim 14, wherein the CPLD is programmed to implement a finite state machine (FSN) having a plurality of defined states including a fault state, and wherein a fault condition is detected when the FSM enters the fault state.

16. The computing platform of claim 9, wherein each of the one or more DIMMs is a DDR5 (Double Data Rate 5^{th} generation) DIMM.

17. A method implemented on a compute platform including a main board (MB) having wiring for interconnecting a plurality of components mounted on or operatively coupled to the main board, including, a processor with an integrated memory controller (iMC), a main board voltage regulator (MBVR), coupled to at least one voltage supply and configured to provide regulated voltage input to the processor, and one or more Dual Inline Memory Modules, each including a Power Management Integrated Chip (PMIC) and having one or more input pins coupled to a voltage source, the method comprising:
monitoring an operating state of the MBVR;
monitoring an operating state of the PMIC for each of the one or more DIMMs; and
in response to detecting a fault condition of the MBVR or a PMIC for a DIMM, prevent reverse bias voltage in circuitry in at least one of the iMC and the one or more DIMMs.

18. The method of claim 17, wherein the method is implemented via VR interlock circuitry coupled to the main board and interconnected to the MBVR and each of the one or more DIMMs.

19. The method of claim 17, wherein the iMC includes a memory channel interface comprising a first plurality of transmit and receive input/output (I/O) buffers for transmitting and receiving data over a DQ bus for a memory channel, and wherein a first DIMM includes a memory channel interface comprising a second plurality of transmit and receive I/O buffers for transmitting and receiving data over the DQ bus, and wherein in response to detecting a fault condition putting the first and second pluralities of transmit and receive I/O buffers into a tri-state mode.

20. The method of claim 19, wherein the first DIMM is a DDR5 (Double Data Rate 5^{th} generation) DIMM, and wherein the first and second pluralities of transmit and receive I/O buffers are put into the tri-state mode within 50 nanoseconds of detecting the fault condition.
